(19) United States
(12) Patent Application Publication
(10) Pub. No.: US 2023/0317712 A1
(43) Pub. Date: Oct. 5, 2023

(54) ESD PROTECTION CIRCUIT AND SEMICONDUCTOR DEVICE

(71) Applicant: ABLIC Inc., Tokyo (JP)

(72) Inventor: Kaku IGARASHI, Tokyo (JP)

(73) Assignee: ABLIC Inc., Tokyo (JP)

(21) Appl. No.: 18/190,939

(22) Filed: Mar. 27, 2023

(30) Foreign Application Priority Data
Mar. 31, 2022 (JP) 2022-058606
Sep. 27, 2022 (JP) 2022-153640

(51) Int. Cl. H01L 27/02; H02H 9/00; H02H 9/04

(52) U.S. Cl. CPC H01L 27/0274; H02H 9/005; H02H 9/04

(57) ABSTRACT

The ESD protection circuit includes an off transistor including: a P-type semiconductor substrate; an N-type well region formed in an upper portion of the semiconductor substrate; an N-type drain region formed in an upper portion of the well region and having a higher impurity concentration than the well region; an N-type source region formed apart from the drain region in the upper portion of the well region and having a higher impurity concentration than the well region; a gate insulating film formed between the drain region and the source region; a gate electrode formed on a surface of the gate insulating film; and a P-type high-concentration region formed in the upper portion of the well region to be in contact with at least the drain region near a corner portion of a channel region and having a higher impurity concentration than the well region.

### CROSS-REFERENCE TO RELATED APPLICATION

This application claims the priority benefits of Japanese application no. 2022-058606, filed on Mar. 31, 2022, and Japanese application no. 2022-153640, filed on Sep. 27, 2022. The entirety of each of the above-mentioned patent applications is hereby incorporated by reference herein and made a part of this specification.

### BACKGROUND

### Technical Field

The present invention relates to an ESD protection circuit and a semiconductor device.

### Description of Related Art

A semiconductor device is often provided with an ESD protection circuit to protect an internal circuit from electro-static discharge (ESD).

Examples of the ESD protection circuit include circuits using independently or parasitically formed diode elements, bipolar elements, thyristor elements, etc. Among these, a so-called “off transistor” is well known, which is used in an off state by connecting the drain of an N-type MOS (Metal-Oxide-Semiconductor) transistor to an external terminal and grounding the gate and the source. This off transistor allows a surge current due to ESD to flow to a ground potential terminal, etc. of a mounting substrate and prevents the internal circuit from being damaged by electro-static discharge.

There are various proposals for such an off transistor. For example, for the purpose of improving the characteristics of ESD protection, an off transistor has been proposed, which is connected with an RC timer in which a resistance element and a capacitance element are connected in series.

### SUMMARY

One aspect of the present invention provides an ESD protection circuit capable of protecting an internal circuit even against electro-static discharge having a short rise time.

An ESD protection circuit in accordance with an embodiment of the present invention includes an off transistor, which includes: a semiconductor substrate of a first conductivity type; a well region of a second conductivity type, formed in an upper portion of the semiconductor substrate; a drain region of the first conductivity type, formed in an upper portion of the well region and having an impurity concentration higher than an impurity concentration of the well region; a source region of the first conductivity type, formed apart from the drain region in the upper portion of the well region and having an impurity concentration higher than the impurity concentration of the well region; a gate insulating film formed on a surface of the semiconductor substrate between the drain region and the source region; a gate electrode formed on a surface of the gate insulating film; and a high-concentration region of the second conductivity type, formed in the upper portion of the well region to be in contact with at least the drain region near a corner portion of a channel region and having an impurity concentration higher than the impurity concentration of the well region.

According to one aspect of the present invention, it is possible to provide an ESD protection circuit capable of protecting an internal circuit even against electro-static discharge having a short rise time.

### BRIEF DESCRIPTION OF THE DRAWINGS

FIG. 1 is a plan view illustrating the off transistor according to an embodiment.

FIG. 2 is a schematic cross-sectional view of the off transistor illustrated in FIG. 1 along the line II-II.

FIG. 3 is a schematic cross-sectional view of the off transistor illustrated in FIG. 1 along the line III-III.

FIG. 4 illustrates an example of a circuit diagram of the semiconductor device including the ESD protection circuit using the off transistor illustrated in FIG. 1 to FIG. 3.

FIG. 5 is a plan view illustrating the conventional off transistor.

FIG. 6 is a schematic cross-sectional view of the off transistor illustrated in FIG. 5 along the line VI-VI.

FIG. 7 is a schematic cross-sectional view of the off transistor illustrated in FIG. 5 along the line VII-VII.

### DESCRIPTION OF THE EMBODIMENTS

An ESD protection circuit using an off transistor according to an embodiment of the present invention will be described hereinafter with reference to the drawings. In the following description, for convenience, XYZ axes are set to be orthogonal to each other, and the +Z direction is called the upper layer side and the −Z direction is called the lower layer side.

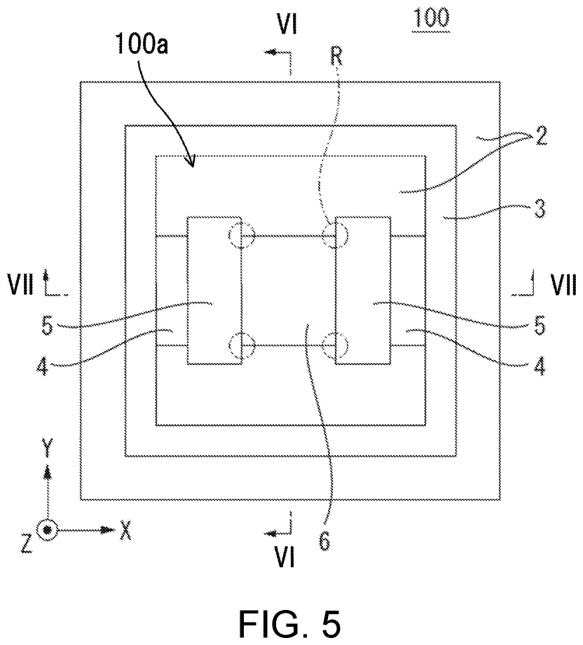

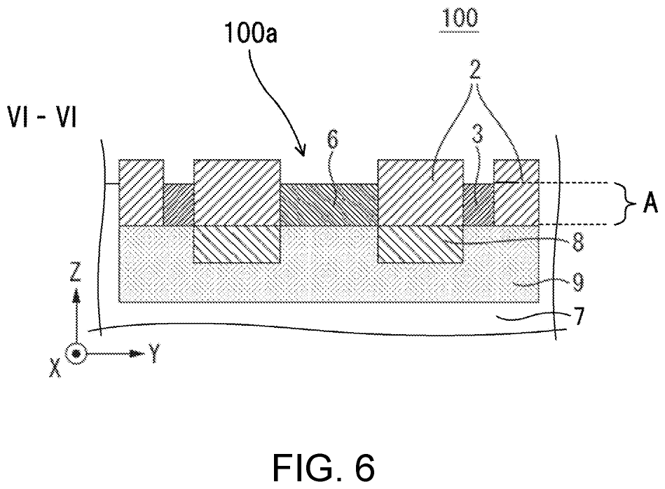

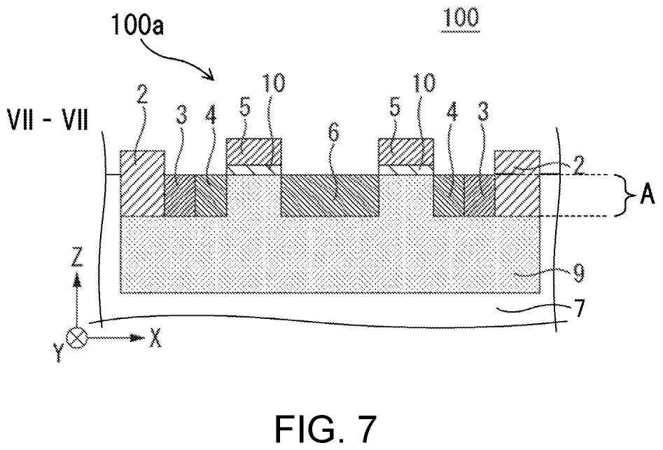

FIG. 5 to FIG. 7 illustrate an ESD protection circuit 100 using a conventional general MOS (Metal Oxide Semiconductor) field effect transistor as an off transistor 100a. The ESD protection circuit 100 includes a drain region 6 in an upper portion A of a P-type well region 9 formed on a surface of an N-type semiconductor substrate 7, and a source region 4 formed apart from the drain region 6 in the same layer direction (X direction) in the upper portion A. The ESD protection circuit 100 includes a gate electrode 5 on the upper layer side of a channel region between the drain region 6 and the source region 4. In addition, a gate insulating film 10 is formed between the layers of the gate electrode 5 and a well region 9. The gate electrode 5 is formed by implanting an N-type impurity into polycrystalline silicon to a high concentration.

A peripheral wall portion 3 which separates the region for forming the transistor is formed around the drain region 6, the source region 4, and the gate electrode 5. The peripheral wall portion 3 is formed by implanting a P-type impurity into a part of the upper portion A of the well region 9 to a high concentration. In the region inside the peripheral wall portion 3 as viewed in the plan view, a high-concentration region 8 obtained by implanting a P-type impurity to a high concentration is formed in the region excluding the drain region 6, the source region 4, and the gate electrode 5. Insulating films 2 are respectively formed on the portions exposed on the upper surface side of the high-concentration region 8 and the upper surface side of the well region 9. The insulating film 2 is, for example, an oxide film such as silicon dioxide, and is formed by LOCOS (Local Oxidation of Silicon) or the like.

In the case where the off transistor 100a is viewed in a plan view from the Z direction, a so-called corner portion R (see FIG. 5) of the channel region tends to have a locally high electric field strength during occurrence of ESD. Then, during occurrence of ESD, if a surge current flows from the drain region 6 into the high-concentration region 8 due to the snapback operation of the parasitic bipolar transistor of the off transistor 100a, the current which flows after the snapback operation may concentrate on and break the corner portion R.

Furthermore, as semiconductor devices are miniaturized due to the demand for high-density mounting in mobile terminals or the like in recent years, the parasitic resistance and parasitic capacitance in the path from the external terminal to the semiconductor chip may be reduced and the rise time of a surge voltage may be shortened. In particular, in the charged device model (CDM) among electro-static discharge models, the rise time of the surge voltage is short, and the off transistor structures proposed so far may not be able to protect the internal circuits of miniaturized semiconductor devices.

Thus, in order to suppress electro-static breakdown at the corner portion R caused by ESD with a short rise time of surge voltage such as CDM, an embodiment of the present invention provides a structure which forms a region having a high impurity concentration at least in the well region near the corner portion to facilitate the current flow.

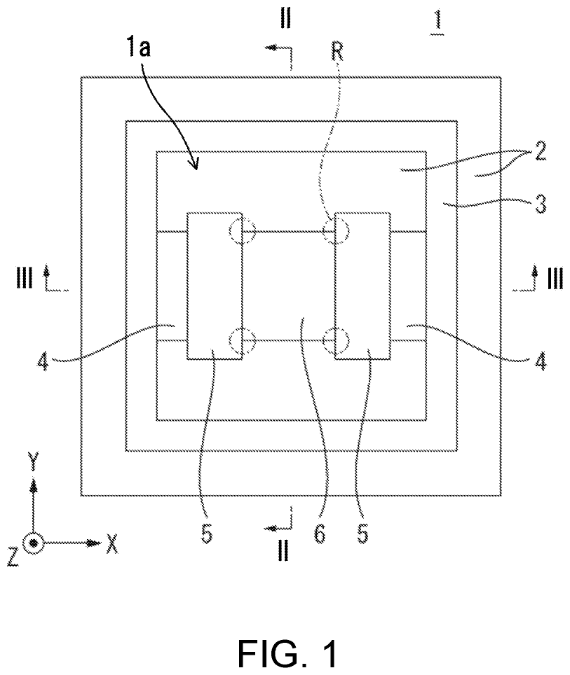

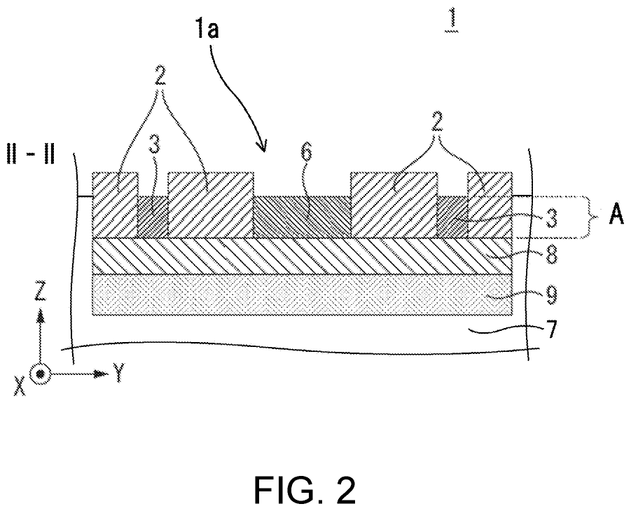

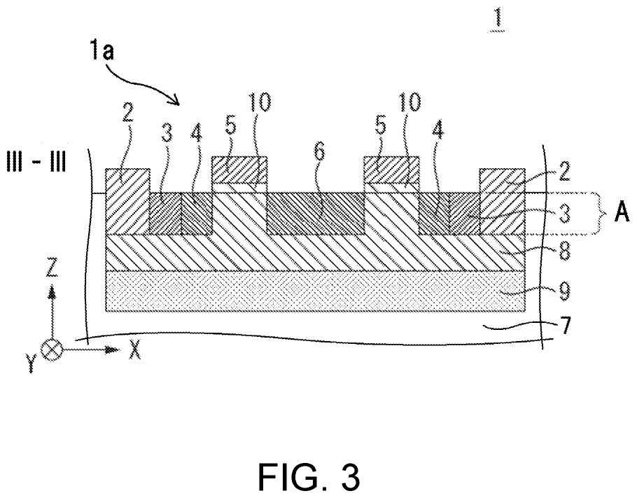

FIG. 1 to FIG. 3 illustrate an off transistor according to an embodiment of the present invention. The ESD protection circuit 1 is formed using the off transistor 1a. The off transistor 1a is formed on a semiconductor substrate 7. The semiconductor substrate 7 is formed of a P-type silicon substrate, and a well region 9 formed by implanting a P-type impurity is provided on the surface. In an upper portion A of the well region 9, a drain region 6 and a pair of source regions 4 formed apart from the drain region 6 in the same layer direction (X direction) are formed by implanting an N-type impurity to a high concentration. The drain region 6 and the source regions 4 are formed in a rectangular shape as viewed in a plan view from the Z direction.

A high-concentration region 8 is formed in the entire upper portion of the well region 9 including a channel region between the drain region 6 and the source region 4. The high-concentration region 8 is formed by implanting a P-type impurity to a high concentration. Agate electrode 5 is formed on the upper layer side of the high-concentration region 8 between the drain region 6 and the source region 4. The gate electrode 5 is formed by implanting a P-type impurity into polycrystalline silicon to a high concentration. The gate electrode 5 is formed in a rectangular shape in a plan view. A gate insulating film 10 is formed between the gate electrode and the high-concentration region 8. The gate insulating film 10 is formed of, for example, an oxide film such as silicon dioxide.

A peripheral wall portion 3 which separates the region for forming the transistor is formed around the drain region 6, the source region 4, and the gate electrode 5. The peripheral wall portion 3 is formed by implanting a P-type impurity into a part of the upper portion A of the well region 9 to a high concentration. An insulating film 2 is formed on the portion exposed on the upper surface side of the high-concentration region 8. The insulating film 2 is, for example, an oxide film such as silicon dioxide, and is formed by LOCOS or the like.

As described above, in the off transistor 1a of the ESD protection circuit 1, the high-concentration region 8 is formed at least in the well region 9 near the corner portion R, so the resistance in the path of the current flowing after the snapback operation is reduced, making it easy for the surge current to flow. Thus, even though the semiconductor device is compact, the ESD protection circuit 1 can protect the internal circuit from electro-static discharge even against ESD with a short rise time of surge voltage such as CDM.

In addition, in this embodiment, the high-concentration region is formed in the entire upper portion of the well region, but the high-concentration region may be formed at least near the corner portion of the channel region, and may also be formed in the entire channel region.

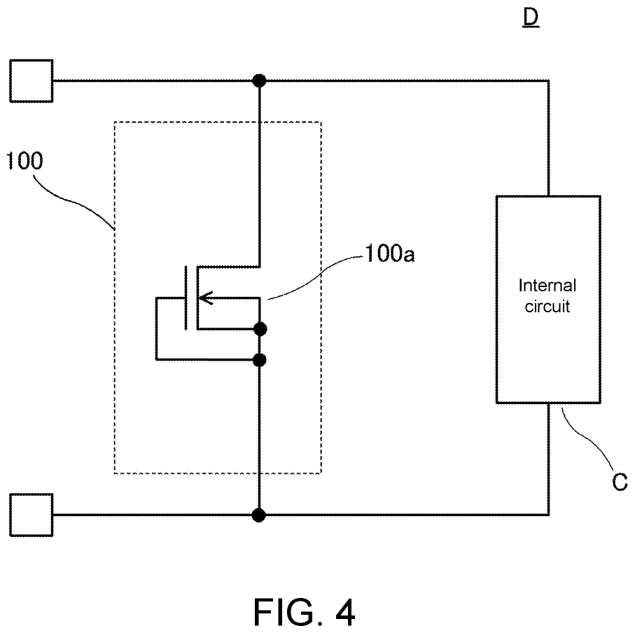

FIG. 4 illustrates an example of a circuit diagram of a semiconductor device including the ESD protection circuit using the off transistor illustrated in FIG. 1 to FIG. 3. As illustrated in FIG. 4, the semiconductor device D is not particularly limited as long as the ESD protection circuit 1 is connected in parallel to an internal circuit (circuit to be protected) C to be protected from electro-static discharge, and can be appropriately selected according to the purpose. Examples of the internal circuit C include a reference voltage generator, a magnetic sensor, etc.

As described above, the ESD protection circuit of this embodiment includes an off transistor which includes a high-concentration region of a second conductivity type, and the high-concentration region is formed in the upper portion of the well region to be in contact with at least the drain region near the corner portion of the channel region and has a higher impurity concentration than the well region. Thus, the ESD protection circuit of this embodiment is capable of protecting the internal circuit of a miniaturized semiconductor device even against ESD with a short rise time of surge voltage such as CDM.

An embodiment of the present invention has been described above, but the present invention is not limited to the above-described embodiment and can be modified as appropriate without departing from the spirit thereof. Furthermore, it is possible to appropriately replace the components in the above-described embodiment with known components without departing from the spirit of the present invention, and the above-described modified examples may also be combined as appropriate.

What is claimed is:

1. An ESD protection circuit, comprising:
an off transistor, which comprises:
a semiconductor substrate of a first conductivity type;
a well region of a second conductivity type, formed in an upper portion of the semiconductor substrate;
a drain region of the first conductivity type, formed in an upper portion of the well region and having an impurity concentration higher than an impurity concentration of the well region;
a source region of the first conductivity type, formed apart from the drain region in the upper portion of the well region and having an impurity concentration higher than the impurity concentration of the well region;
a gate insulating film formed on a surface of the semiconductor substrate between the drain region and the source region;
a gate electrode formed on a surface of the gate insulating film; and
a high-concentration region of the second conductivity type, formed in the upper portion of the well region to be in contact with at least the drain region near a corner portion of a channel region and having an impurity concentration higher than the impurity concentration of the well region.

2. The ESD protection circuit according to claim 1, wherein the high-concentration region is formed in an entire area of the channel region.

3. The ESD protection circuit according to claim 1, wherein the high-concentration region is formed in an entire area of the upper portion of the well region.

4. A semiconductor device, in which the ESD protection circuit according to claim 1 and a protected circuit protected from electro-static discharge by the ESD protection circuit are connected in parallel.
